(19) United States
(12) Patent Application Publication
(10) Pub. No.: US 2006/0154436 A1
(43) Pub. Date: Jul. 13, 2006

(54) Metal-insulator-metal capacitor and a fabricating method thereof

(75) Inventors: Kyong-Min Kim, Ansan-si (KR); Soon-Haeng Lee, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/293,649

(22) Filed: Dec. 2, 2005

(30) Foreign Application Priority Data
Dec. 3, 2004 (KR) 2004-101185

(51) Int. Cl. H01L 21/20

(52) U.S. Cl. 438/396

(57) ABSTRACT

The present invention disclosed herein is a semiconductor capacitor and a method for fabricating the same. A semiconductor capacitor with multitiered metal oxide layers, including at least one metal oxide layer, wherein oxygen ions are implanted therein using a rapid thermal oxidation process in the presence of oxygen gars. Consequently, a capacitor with an improved leakage current characteristic of a dielectric layer is formed.

### CROSS-REFERENCE TO RELATED APPLICATIONS

This U.S. non-provisional patent application claims priority under 35 U.S.C. §119 to Korean Patent Application 2004-101185 filed on Dec. 3, 2004, the entire contents of which are hereby incorporated by reference herein.

### BACKGROUND OF THE INVENTION

This invention is concerned with a method for forming a semiconductor device. In particular, the present invention relates to a method for forming a semiconductor device having a capacitor.

Capacitor sizes have been scaled down in response to the high integration of semiconductor devices. Research studies geared towards these scale down requirements have been actively pursued.

In general, a capacitor comprises a lower electrode, an upper electrode, and a dielectric layer interposed between the upper and lower electrodes. It is desirable that the electrostatic capacitance of the capacitor is increased either by an increased overlap area between the upper and lower electrodes; or, alternatively, by reducing the thickness of the dielectric layer.

Research studies have suggested making a cylindrical capacitor or deep trench capacitor to increase the overlap area between the upper and lower electrodes. However, the increase in area is still limited and fails to meet the size integration in a semiconductor device. While the alternative of reducing the thickness of the dielectric layer to increase the electrostatic capacitance is also disadvantageous because of a leakage current characteristic between the upper and lower electrodes.

Another solution to increase the electrostatic capacitance of the capacitor is a method for increasing the dielectric constant of the dielectric layer. The method suggests that the electrostatic capacitance of the capacitor is increased by using a high k-dielectric layer material as a dielectric layer.

In a conventional semiconductor device using a high k-dielectric material as a dielectric layer, the capacitor upper and lower electrodes are made of a metal or silicon layer and a high k-dielectric material is formed between the electrodes as a dielectric layer. The high k-dielectric layer is formed, in general, of any metal oxide, but preferably of aluminum oxide, hafnium oxide or similar materials or combinations thereof.

Aluminum oxide has an excellent leakage current characteristic and is limited to a single layer use due to its low dielectric constant (8˜10). Hafnium oxide has a relatively high dielectric constant (˜20), but it is difficult to manage the leakage current characteristic. To overcome these characteristics, a multitiered layer (aluminum oxide/hafnium oxide) as a dielectric layer of a capacitor is used in applications of a conventional MDL (Merged DRAM Logic) Device and memory products. In the fabrication of the multitiered combination (aluminum oxide/hafnium oxide) of a dielectric layer, hafnium oxide is crystallized at a relatively high temperature. This crystallized hafnium oxide has a grain boundary, thereby degrading leakage current characteristic.

### SUMMARY OF THE INVENTION

Preferred embodiments of the invention provide a method for forming a semiconductor device with a metal-insulator-metal capacitor with an improved leakage current of a dielectric layer.

In an embodiment of the present invention, there is provided a method for fabricating a semiconductor device comprising the steps of: forming a capacitor lower electrode on a semiconductor substrate; forming a high k-dielectric layer including at least a metal oxide layer on the lower electrode; performing a rapid thermal oxidation process with respect to the high k-dielectric layer; and depositing a capacitor upper electrode on an upper portion of the high k-dielectric layer.

In preferred embodiments of the present invention, the high k-dielectric layer is formed of a multitiered layer.

In still some embodiments of the present invention, the hafnium oxide layer is the uppermost layer of the multitiered layer.

In more embodiments of the present invention, the rapid thermal oxidation process is performed with the flow of gases at a ratio of about 1:5 through about 1:10 of oxygen and nitrogen at a temperature of about 500° C. to about 700° C. for about 10 minutes to about 60 minutes.

### BRIEF DESCRIPTION OF THE DRAWINGS

The accompanying drawings are included to provide a further understanding of the invention, and are incorporated herein to constitute a part of this specification. The drawings show illustrative embodiments of the present invention and, together with the descriptions, serve to explain the principles of the present invention. In the drawings:

FIGS. 1 to 3 are cross-sectional views illustrating a method for forming a semiconductor device having a capacitor according to a preferred embodiment of the present invention; and

FIG. 4 is a cross-sectional view illustrating a method for forming a semiconductor device having a capacitor according to another embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the invention to those skilled in the art. Like numerals refer to like elements throughout the specification.

Hereinafter, a method for fabricating a semiconductor device having a metal-insulator-metal (hereinafter, referred to as a “MIM”) capacitor according to the present invention will be more fully described in conjunction with the accompanying drawings.

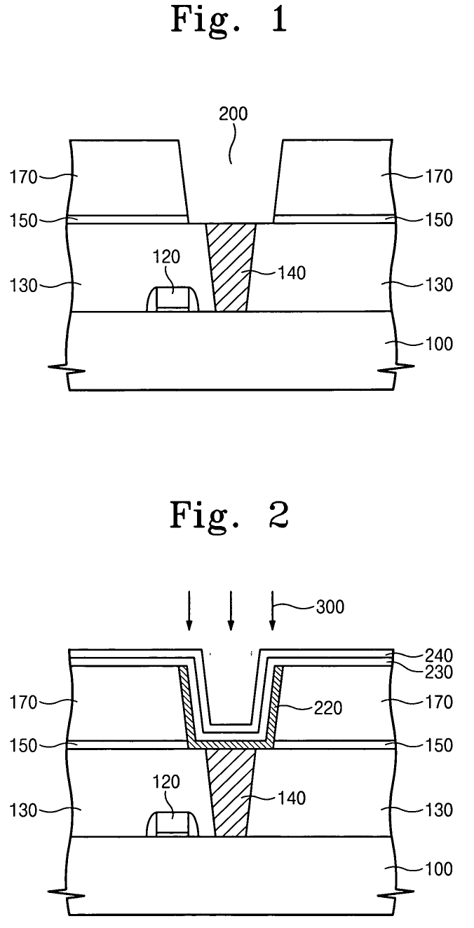

FIGS. 1 to 3 are cross-sectional views illustrating a method for forming a semiconductor device having a capacitor according to at least one embodiment of the present invention.

With reference to FIG. 1, a first interlayer dielectric layer 130 is formed on a semiconductor substrate 100 in which a transistor structure such as a MOS transistor 120 and an interconnection layer (not shown) are formed. The interlayer dielectric layer 130 may be formed of silicon oxide.

A contact plug 140 penetrating the first interlayer dielectric layer 130 to be electrically connected to a predetermined region of a semiconductor substrate 100. The contact plug 140 may be formed of a metal layer such as a doped polysilicon layer or a tungsten layer. In addition, the contact plug 140 may be formed with the use of an etchback process or CMP (Chemical Mechanical Polishing).

An etch stop layer 150 and a second interlayer dielectric layer 170 are sequentially formed on the semiconductor substrate having the contact plug 140. The etch stop layer 150 is made of an insulating layer having an etch selectivity with respect to the first and second interlayer dielectric layers 130 and 170. For example, if the first and second interlayer dielectric layers 130 and 170 are formed of silicon oxide, the etch stop layer may be formed of silicon nitride.

Next, the second interlayer dielectric layer 170 and the etch stop layer 150 are successively patterned to form a trench for exposing an upper surface of the contact plug 140. At this time, the etch stop layer 150 protects the first interlayer dielectric layer from being etched while allowing the second interlayer dielectric layer to be etched.

Continuously, as shown in FIG. 2, a lower electrode 220 is formed on a semiconductor structure having the trench 200.

The lower electrode 220 is conformally formed in the trench. The lower electrode 220 may be made of a conductive layer, preferably a metal layer. For example, the metal layer may comprise a conductive metal oxide layer comprising Ruthenium oxide (RuO), or a conductive metal oxynitride, or a conductive metal nitride (e.g., TaN, TiN). For example, a film of the lower electrode 220 may be formed of TiN. TiN having a thickness of about 400 Å to about 500 Å may be formed by a CMP process using TiCl₄ as a source gas at a temperature of about 500° C. to about 700° C.

Prior to forming the lower electrode 220, an oxidation barrier layer (not shown) may be further formed between the lower electrode 220 and the contact plug 140. The oxidation barrier layer is a conductive layer which functions as an interface between the contact plug 140 and the lower electrode 220; preventing either from being oxidized.

Continuously, the conductive layer is planarized using an etchback process or a CMP process to form the lower electrode 220 in the trench until the upper surface of the second interlayer dielectric layer 170 is exposed.

Continuously, a first dielectric layer 230 is formed by the deposition of an aluminum oxide layer to a thickness of about 10 Å to about 30 Å. The aluminum oxide layer may be formed through ALD (Atomic Layer Deposition) using TMA (Tri-Methyl Aluminum) at a temperature of about 300° C. to about 500° C. Alternatively, the aluminum oxide layer may be formed by the oxidation of aluminum layer.

In more detail, a TMA source is implanted in advance, and followed by an N₂ purge. Next, O₃ is implanted as a reaction gas. These processes are repeatedly performed.

Continuously, a second dielectric layer 240 is formed. For example, a hafnium oxide layer is deposited at a thickness of about 30 Å to about 60 Å. Similarly, the second dielectric layer 240 also uses ALD process. However, the second dielectric layer is formed using TEMAH (Tetra-Ethyl-Methyl-Amine-Hafnium) at a temperature of about 300° C. to about 500° C. Alternatively, the aluminum oxide layer may be formed by the oxidation of aluminum layer.

Continuously, as shown in FIG. 2, a rapid thermal oxidation process 300 is performed to the substrate in which the second dielectric layer 240 is formed. The rapid thermal oxidation process 300 is carried out at a temperature of about 500° C. to about 700° C. for about 10 minutes to about 60 minutes. Due to the rapid thermal oxidation process 300, impurities in the second dielectric layer 240 are removed, and the second dielectric layer 240 is made more dense. Oxygen can be implanted into the second dielectric layer 240 to counteract the effects of the rapid thermal oxidation process 300. The leakage current characteristic of the second dielectric layer 240 is thereby enhanced.

Further, during the rapid thermal oxidation process 300, a source of gas at a ratio of about 1:10 mixture of oxygen and nitrogen flows into the system to suppress an oxidation of the lower electrode. The oxygen source may be one comprising O₂ or O₃. The nitrogen gas may be one comprising N₂ or NH₃.

If the dielectric layer formed by the rapid thermal oxidation process is a high k-dielectric layer, the capacitor may comprise a unit cell of a DRAM or other semiconductor device.

Next, as shown in FIG. 3, an upper electrode 260 is formed on a semiconductor substrate having the dielectric layers 230 and 240 by the rapid thermal oxidation process. The upper electrode 260 is preferably one selected from the group consisting of a conductive metal compound or similar materials thereof. The upper electrode 260 may be formed of the same material as the lower electrode 220. For instance, the upper electrode 260 may be similarly made of TiN film to a thickness of about 200 Å to about 400 Å at a temperature of about 500° C. to about 700° C. and a reaction gas comprising ammonia gas NH₃.

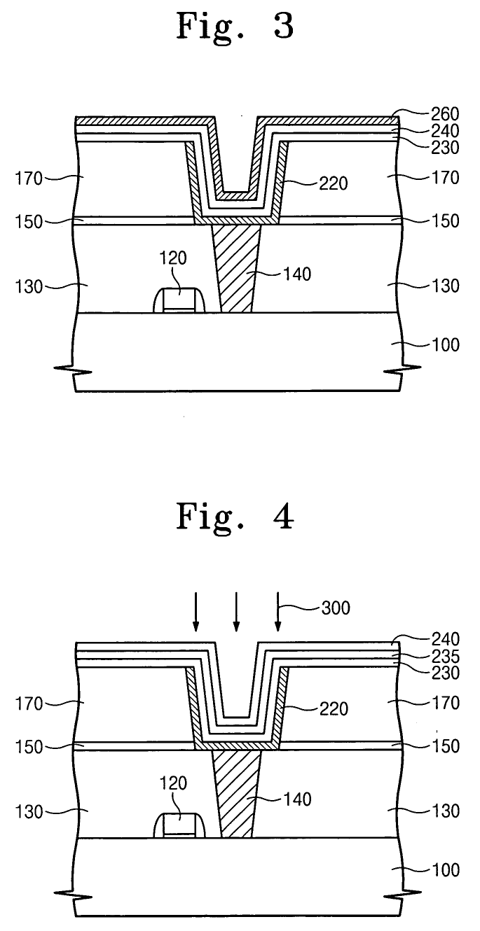

FIG. 4 is a cross-sectional view illustrating a method for forming a semiconductor device having a capacitor according to another embodiment of the present invention.

The description of FIG. 4 is similar to FIG. 1. A first interlayer dielectric layer including a contact plug is formed on a semiconductor substrate 100, and after forming an etch stop layer and a second interlayer dielectric layer, a second interlayer dielectric layer exposing the contact plug is formed. The process for forming a capacitor lower electrode in the trench is the same as FIG. 2 of the first embodiment.

A difference between FIG. 4 and FIG. 1, is that an aluminum oxide layer and a tantalum oxide layer are stacked, for example, the aluminum oxide layer being a first dielectric layer 230 is located on the lower electrode, and the tantalum oxide layer being a third dielectric layer is located below a hafnium oxide layer.

The exemplary rapid thermal oxidation process 300 is applied to the semiconductor substrate onto which the second and third dielectric layers 235 and 240 are formed. The rapid thermal oxidation process 300 is performed at a temperature of about 500° C. to about 700° C. for about 10 minutes to about 60 minutes. Due to the rapid thermal oxidation process 300, impurities in the second dielectric layer 240 are removed, and the second dielectric layer is more integrated.

Next, as shown in FIG. 3 of the first embodiment, an upper electrode is similarly formed on a semiconductor substrate, as shown in FIG. 4, having the dielectric layers 235 and 240 using the rapid thermal oxidation process.

As illustrated in the aforementioned descriptions of a semiconductor device having the described capacitor, the leakage current due to the dielectric characteristic degradation can be suppressed by inserting oxygen gas into the hafnium oxide layer during the rapid thermal oxidation process.

Although the present invention has been described in connection with the embodiments of the present invention illustrated in the accompanying drawings, it is not limited thereto. It will be apparent to those skilled in the art that various substitution, modifications and changes may be added thereto without departing from the scope and spirit of the invention.

What is claimed is:

1. A method of fabricating a semiconductor device comprising:
forming a capacitor lower electrode on a semiconductor substrate;
forming a dielectric layer including at least metal oxide layer on the lower electrode;
performing a rapid thermal oxidation process with respect to the dielectric layer; and
depositing a capacitor upper electrode on an upper portion of the dielectric layer.

2. The method as set forth in claim 1, wherein the dielectric layer is formed of a multitiered layer and has a high k value.

3. The method as set forth in claim 2, wherein at least one layer of the multitiered layer includes a hafnium oxide layer.

4. The method as set forth in claim 3, wherein the hafnium oxide layer is formed using a Tetra-Ethyl-Methyl-Amine-Hafnium source.

5. The method as set forth in claim 3, wherein the hafnium oxide layer is the uppermost layer of the multitiered layer.

6. The method as set forth in claim 2, wherein the multitiered layer is formed by sequentially stacking aluminum oxide and hafnium oxide.

7. The method as set forth in claim 2, wherein the multitiered layer is formed by sequentially stacking aluminum oxide, tantalum oxide, and hafnium oxide.

8. The method as set forth in claim 1, wherein the rapid thermal oxidation process is performed between about 500° C. and about 700° C.

9. The method as set forth in claim 8, wherein the rapid thermal oxidation process is performed for about 10 minutes to about 60 minutes.

10. The method as set forth in claim 7, wherein the rapid thermal oxidation process is performed with a flow of ambient gases at about 1:5 through about 1:10 ratios of oxygen and nitrogen.

11. The method as set forth in claim 7, wherein the lower and upper electrodes include titanium nitride.

12. The method as set forth in claim 7, wherein the hafnium oxide layer is formed at a thickness of about 30 Å to about 60 Å.

13. The method as set forth in claim 7, wherein the aluminum oxide layer is formed at a thickness of about 10 Å to about 30 Å.

14. The method as set forth in claim 7, wherein the aluminum oxide layer is formed using TMA (Tri-Methyl Aluminum).

15. The method as set forth in claim 14, where in the aluminum oxide layer is formed at a temperature of about 300° C. to about 500° C.

16. A method of fabricating a semiconductor device comprising:
forming a capacitor electrode on a substrate;
forming a high k-dielectric metal oxide layer on the capacitor electrode and performing a rapid thermal oxidation process and implanting oxygen ions; and
forming another capacitor electrode on the high k-dielectric metal oxide layer.

17. The method as set forth in claim 16, wherein the high-k dielectric layer is formed by stacking multitiered metal oxide layers.

18. The method as set forth in claim 17, wherein the multitiered layers comprise aluminum oxide, tantalum oxide, hafnium oxide, or any combination thereof.
